(19) United States
(12) Patent Application Publication
(10) Pub. No.: US 2026/0066033 A1
(43) Pub. Date: Mar. 5, 2026

(54) MEMORY PACKAGES WITH BUFFER DIE WITH PARALLEL ERROR DETECTION AND CORRECTION

(71) Applicant: Micron Technology, Inc., Boise, ID (US)

(72) Inventors: Navid Lashkarian, Pleasanton, CA (US); Randall J. Rooney, Boise, ID (US); Matthew A. Prather, Boise, ID (US); Anthony D. Veches, Boise, ID (US); Sujeet Ayyapureddi, Boise, ID (US)

(73) Assignee: Micron Technology, Inc., Boise, ID (US)

(21) Appl. No.: 19/291,212

(22) Filed: Aug. 5, 2025

Related U.S. Application Data
(60) Provisional application No. 63/689,068, filed on Aug. 30, 2024.

(51) Int. Cl. G11C 29/52; G11C 11/4093; G11C 11/4096

(52) U.S. Cl. CPC G11C 29/52; G11C 11/4093; G11C 11/4096

(57) ABSTRACT

A memory package may include multiple memory devices and a buffer die in some examples. The memory package may utilize Reed Solomon (RS) coding for error detection and correction. The computations for RS coding may be divided between the memory devices and/or the buffer die. One or more computations for generating a codeword from data may be performed by the buffer die, and the codeword may be stored in one or more of the memory devices in some examples. In some examples, the memory devices may perform computations for determining a syndrome for the codeword. One or more of the computations may be performed in parallel. In some examples, the buffer die may perform computations based on results of the of memory devices to arrive at the syndrome.

### CROSS REFERENCE TO RELATED APPLICATION(S)

This application claims the benefit under 35 U.S.C. § 119 of the earlier filing date of U.S. Provisional Application No. 63/689,068 filed Aug. 30, 2024, the entire contents of which is hereby incorporated by reference in its entirety for any purpose.

### BACKGROUND

This disclosure relates generally to semiconductor devices, and more specifically to semiconductor memory devices. In particular, the disclosure relates to memory, such as dynamic random access memory (DRAM). Information may be stored in memory cells, which may be organized into rows (word lines) and columns (bit lines) of an array. Various types of information may be stored in the array, such as data, error correction code (ECC) data, and metadata. The data may be information provided by an external device (e.g., controller, processor, host system). The ECC data may provide information that may be used to detect and/or correct errors in the data. The metadata may provide information about the data, ECC data, the memory device, and/or a device in communication with the memory device (e.g., a controller).

Semiconductor memory devices may store information in multiple memory cells. The information may be stored as a binary code, and each memory cell may store a single bit of information as either a logical high (e.g., a “1”) or a logical low (e.g., a “0”). The memory cells may be organized at the intersection of word lines (rows) and bit lines (columns) an array. The memory may further be organized into one or more memory banks. The banks may be organized into bank groups, where each bank group includes one or more banks. Each bank may include multiple of rows and columns. During operations, the memory device may receive a command and an address which specifies one or more rows and one or more columns and then execute the command on the memory cells at the intersection of the specified rows and columns (and/or along an entire row/column). The address may further specify the bank group and/or bank for execution of the command. In some applications, rows may be specified by 17-bit row addresses and columns may be specified by 12-bit column addresses. However, the number of bits used for the addresses may vary depending on the size and/or organization of the memory.

The columns may generally be organized into column planes, each of which includes a number of sets of individual columns all activated by a column select signal (CS) (e.g., column selects). Each bank may include some number X column planes. A column plane may receive some number N of column select (CS) signals, each of which may activate some number M of individual bit lines. As used herein, a column select set or CS set may generally refer to a set of bit lines which are activated by a given value of the CS signal within a column plane. The column select signal may be represented by (all or a portion of) a column address (CA). Responsive to a column select signal, data may be provided from corresponding locations from the column planes. The data from the column planes associated with the column select signal may be referred to as a cache line.

In many applications, multiple memory devices are used by a device and/or computing system. The memory devices may be packaged together in a memory module. For example, single in-line memory modules (SIMMs), dual in-line memory modules (DIMMS), small outline DIMMs (SODIMMs), and rambus in-line memory modules (RIMM) may include multiple memory devices.

FIG. 1A is a block diagram of at least a portion of a computing system. The computing system 10 includes a memory module 12 and a controller 16 in communication with the memory module 12. The memory module 12 may include module logic and buffers 18 and one or more memory devices 14.

The controller 16 may provide commands, addresses (CA), clock signals (CLK), and/or to one or more of the memory devices 14 and receive data from one or more of the memory devices 14. As shown, some or all of the signals transmitted between the controller 16 and memory devices 14 must pass through the module logic and buffers 18. The module logic and buffers 18 may facilitate coordination between the memory devices 14 (e.g., distributing clock signals). However, module logic and buffers 18 may also lead to “middleman” inefficiencies. Further, the module logic and buffers 18 are typically manufactured by an entity different from the entities that manufactured the memory devices 14 and controller 16. This may lead to quality control issues and/or unforeseen compatibility issues. In some instances, this may lead to limitations in error correction capabilities.

### BRIEF DESCRIPTION OF THE DRAWINGS

FIG. 1A is a block diagram of at least a portion of a computing system.

FIG. 1B is a block diagram of at least a portion of a computing system according to some embodiments of the present disclosure.

FIG. 2A is a diagram showing a multi-die device according to an embodiment of the disclosure.

FIG. 2B is a diagram showing a multi-die device according to an embodiment of the disclosure.

FIG. 2C is a block diagram of a memory device according to some embodiments of the present disclosure.

FIG. 3 is a functional block diagram of a memory package according to at least one embodiment of the disclosure.

FIG. 4 illustrates division of computations for a write operation in a memory package according to at least one embodiment of the disclosure.

FIG. 5 illustrates division of computations for a read operation in a memory package according to at least one embodiment of the disclosure.

FIG. 6 is a flow chart of a method according to at least one embodiment of the present disclosure.

FIG. 7 is a flow chart of a method according to at least one embodiment of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed apparatus, systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory package may include a stack of memory devices and at least one buffer die. The buffer die may include components that facilitate communication with a controller and/or host system. The buffer die may include components that facilitate communication between memory packages. The memory packages may be included on a memory module. The buffer die of the memory packages may reduce or eliminate the need for additional devices on memory modules (e.g., buffers, logic). This may reduce reliability and/or compatibility issues in some applications. In some applications, it may provide faster communication between the memory package and the controller and/or host system.

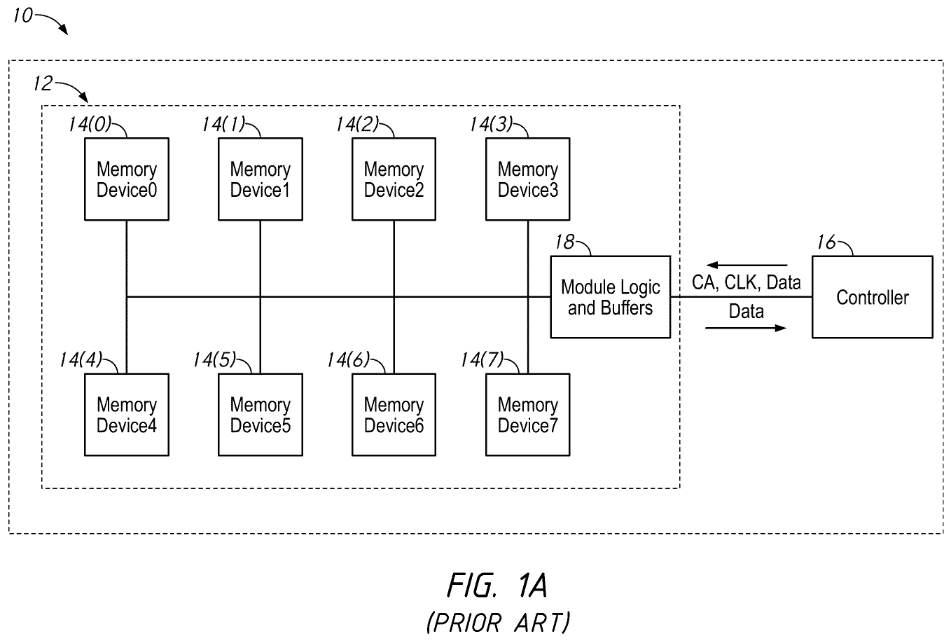

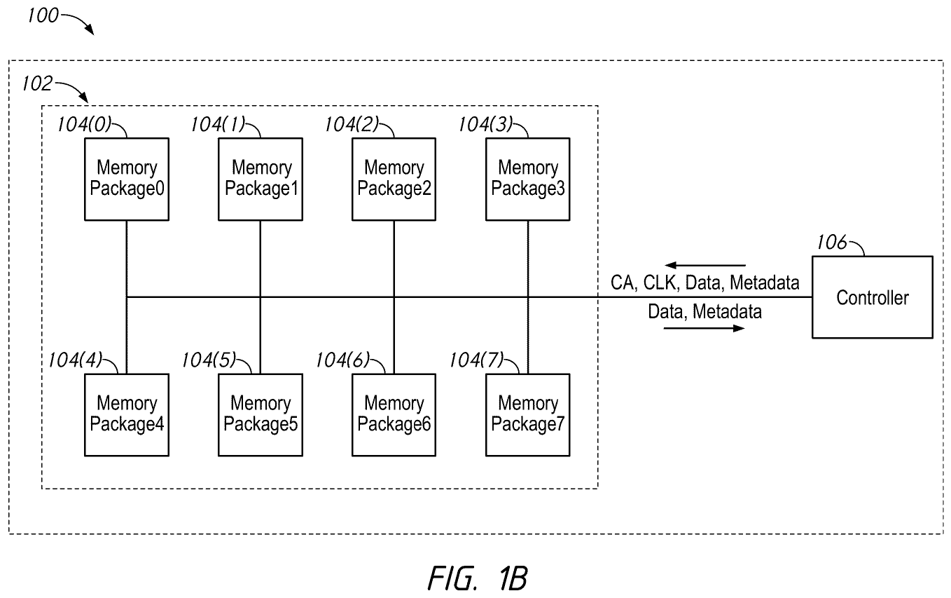

FIG. 1B is a block diagram of at least a portion of a computing system according to some embodiments of the present disclosure. The computing system 100 includes a memory module 102 and a controller 106 in communication with the memory module 102. In some embodiments, the controller 106 may be included in a processor (not shown) or in communication with the processor. The memory module 102 may include one or more memory packages 104. According to embodiments of the present disclosure, each memory package 104 may one or more memory devices and a buffer die. The memory devices may be stacked on the buffer die in some examples. In the example shown in FIG. 1, there are eight memory packages 104(0-7). However, in other embodiments, there may be more or fewer memory packages (e.g., 1 device, 2, devices, 4 devices, 16 devices). In some embodiments, additional memory packages 104 may be included to provide for redundancy. In some embodiments, memory module 102 may be a dual in-line memory module (DIMM). In some embodiments, what is shown in FIG. 1 may represent only half of the DIMM (e.g., one of the two channels). In other words, memory module 102 may include sixteen memory packages 104.

The controller 106 may provide signals such as commands, addresses, clock signals and/or data (e.g., data, metadata, or both) to one or more of the memory packages 104 and receive signals such as data from one or more of the memory packages 104. According to embodiments of the present disclosure, the controller 106 may provide and receive signals from the memory die via the buffer die. In some embodiments, memory package 104 may be x16 or x32 memory devices. That is, either 16 or 32 DQ terminals (e.g., pins) may be active. In some embodiments, the memory package 104 may support both x16 and x32 operation. In some embodiments, whether the memory package 104 operate in x4 or x8 mode may be based, at least in part, on values stored in mode registers (not shown in FIG. 1) of the memory packages 104. In some embodiments, the memory packages 104 may be x4, x8, or x64 memory packages.

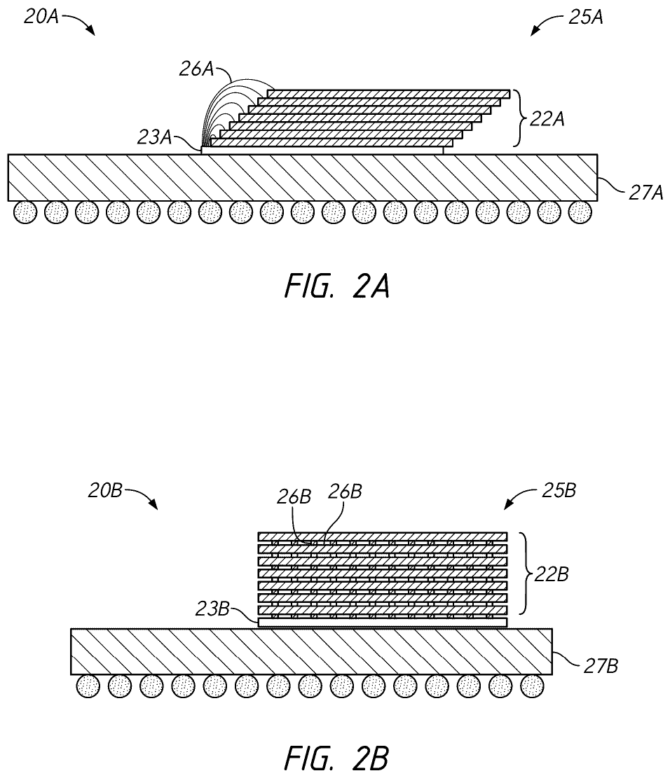

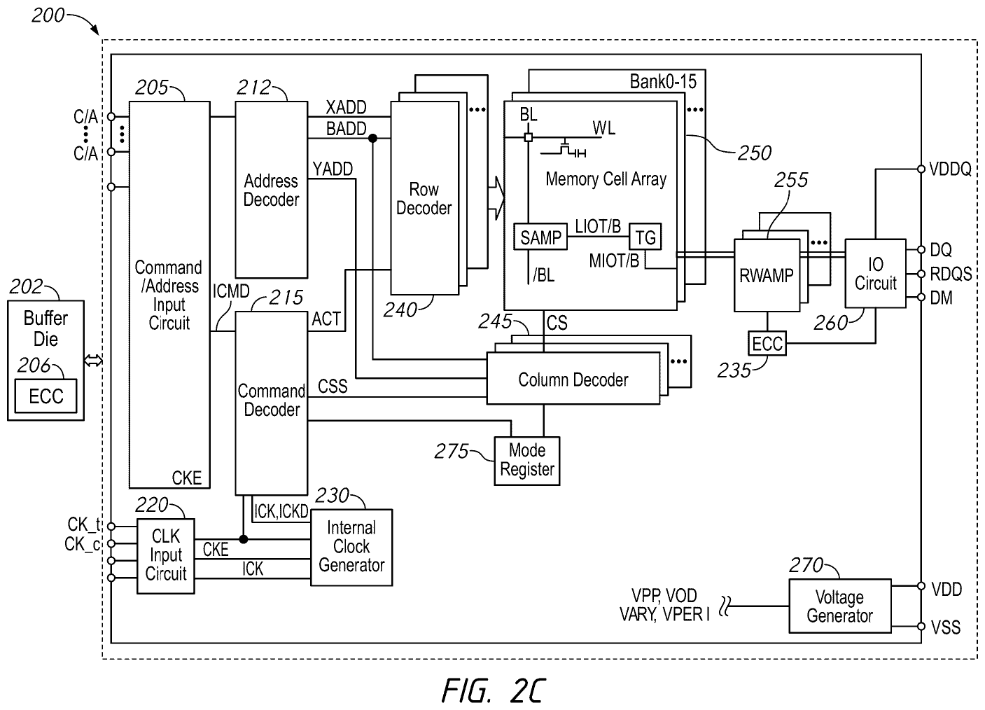

FIG. 2A is a diagram showing a multi-die device according to an embodiment of the disclosure. The multi-die device 20A may include a stack 25A of memory devices 22A (e.g., memory die) and a buffer die 23A. Embodiments of the disclosure are not limited to the particular number of memory devices 22A included in the stack 25A shown in FIG. 2A. For example, the stack 25A may include 1-16 memory devices 22A. Further, while one buffer die 23A is shown in FIG. 2A, in some embodiments, there may be two buffer die 23A per stack 25A. In some embodiments of the disclosure, the stack 25A may be included in one or more of memory packages 104.

The memory devices 22A and buffer die 23A may be stacked in a staggered manner, providing a “shingle-stack” configuration for the stack 25A as shown in FIG. 2A. However, the memory devices 22A and buffer die 23A may be stacked in other configuration such as a staggered configuration. The memory devices 22A and/or buffer die 23A may be attached to one another. In some embodiments of the disclosure, the semiconductor devices 22A are attached to one another by an adhesive epoxy.

The memory devices 22A and/or buffer die 23A may include a pad formation area, a peripheral circuit area, and memory cell array areas (not shown in FIG. 2A) that include memory cells, circuits, and signal lines, for example, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 22A and/or buffer die 23A.

The pad formation area may include a plurality of bond pads disposed along the edge of the memory devices 22A and/or buffer die 23A. The plurality of bond pads may be coupled to the terminals of the semiconductor device and represent external terminals of the memory devices 22A and/or buffer die 23A. For example, the plurality of bond pads may include data terminals, command and address terminals, clock terminals, and/or power supply terminals.

Circuits included in the memory cell array area and/or circuits of the peripheral circuit area may be coupled to one or more bond pads included in the pad formation area. Various circuits of the memory devices 22A and/or buffer die 23A may be coupled to the terminals. Conductive structures may be used to couple the terminals to one or more of the bond pads. As a result, the circuits coupled to the terminals are also coupled to the bond pads. The conductive structures may extend from locations of the terminals included in the memory cell array area and/or the peripheral circuit area to the pad formation area.

The memory devices 22A may be offset from one another to allow edge regions of the memory devices 22A to be exposed. The exposed edge regions may include the bond pads to which conductors 26A may be coupled. In some embodiments of the disclosure, the bond pads of the edge regions may be conductive pads. The bond pads may be coupled to terminals of the respective memory device 22A. In some embodiments of the disclosure, the conductors 26A are bond wires. While the conductors 26A in FIG. 2A are shown coupling all of the memory devices 22A to the buffer die 23A, the conductors 26A may be coupled in other configurations. For example, the conductors 26A may couple adjacent memory devices 22A to one another, and the lowest memory device 22A may be coupled to the buffer die 23A by the conductors 26A in a “daisy chain” configuration.

The stack 25A may be attached to a substrate 27A. The stack 25A may be attached to the substrate 27A by an adhesive epoxy in some embodiments of the disclosure. The substrate 27A may include conductive signal lines to route signals along the substrate, for example, to and from the memory devices 22A and/or buffer die 23A. Other circuits may also be attached to the substrate 27A and coupled to the conductive signals lines as well. As a result, the circuits attached to the substrate 27A may be coupled, for example, to the memory devices 22A and/or buffer die 23A through the conductive signal lines of the substrate 27A and conductors coupled to the conductive signal lines and the bond pads of the memory devices 22A and/or buffer die 23A. In some embodiments, the substrate 27A may be included in memory module 102.

FIG. 2B is a diagram showing a multi-die device according to an embodiment of the disclosure. The multi-die device 20B may include a stack 25B of memory devices 22B and a buffer die 23B. Embodiments of the disclosure are not limited to the particular number of memory devices 22B included in the stack 25B shown in FIG. 2B. For example, the stack 25B may include 1-16 memory devices 22B. Further, while one buffer die 23B is shown in FIG. 2B, in some embodiments, there may be two buffer die 23B per stack 25B. In some embodiments of the disclosure, the stack 25B may be included in one or more of the memory packages 104.

The memory devices 22B and/or buffer die 23B may include a pad formation area, a peripheral circuit area, and memory cell array areas (not shown in FIG. 2B) that include memory cells, circuits, and signal lines, for example, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 22B and/or buffer die 23B.

The memory devices 22B and buffer die 23B may be stacked in an aligned manner, such that the edges of the memory devices 22B are substantially aligned. When the buffer die 23B is a similar dimension to the memory devices 22B, the buffer die 23B may be substantially aligned with the memory devices 22B as well as shown in FIG. 2B. However, the memory devices 22B and buffer die 23B may be stacked in other configuration such as a staggered configuration.

In contrast to stack 25A, the memory devices 22B and/or buffer die 23B are electrically coupled to one another by through silicon vias (TSVs) 26B rather than being coupled by conductors 26A. In some embodiments, instead of or in addition to pad formation areas, the memory devices 22B and/or buffer die 23B may include TSV formation areas. The memory devices 22B and/or buffer die 23B may be physically attached to one another by additional mechanisms (e.g., not just the TSVs). In some embodiments of the disclosure, the semiconductor devices 22B are attached to one another by an adhesive epoxy.

The stack 25B may be attached to a substrate 27B. The stack 25B may be attached to the substrate 27B by an adhesive epoxy in some embodiments of the disclosure. The substrate 27B may include conductive signal lines to route signals along the substrate, for example, to and from the memory devices 22B and/or buffer die 23B. Other circuits may also be attached to the substrate 27B and coupled to the conductive signals lines as well. As a result, the circuits attached to the substrate 27B may be coupled, for example, to the memory devices 22B and/or buffer die 23B through the conductive signal lines of the substrate 27B and conductors coupled to the conductive signal lines and the bond pads of the memory devices 22B and/or buffer die 23B. In some embodiments, the substrate 27B may be included in memory module 102.

In some embodiments, the buffer die 23A, 23B is a memory device substantially similar to memory devices 22A, 22B. In some embodiments, memory devices 22A, 22B may have certain logic circuits disabled and/or bypassed, and the buffer die 23A, 23B has such logic circuits enabled and acts as a “target” or “master” die. In some embodiments, the buffer die 23A, 23B is a different device with different components than the memory devices 22A, 22B. As described in more detail herein, the memory devices 22A, 22B and/or buffer die 23A, 23B may include components for managing ECC data. In particular, the memory devices 22A, 22B and/or buffer die 23A, 23B may include components to facilitate divided and/or parallel ECC encoding and decoding.

According to embodiments of the present disclosure, bits associated with a codeword may be distributed across one or more memory devices of a memory package. The memory devices may perform calculations in parallel to determine a syndrome.

FIG. 2C is a block diagram of a memory device according to some embodiments of the present disclosure. The apparatus may be a semiconductor device. In some embodiments, the memory device 200 may include, without limitation, a dynamic random access (DRAM) device integrated into a single semiconductor chip. In some examples, the DRAM may be a double data rate (DDR) memory device. In some embodiments, it may be a DDR5 or DDR6 memory device. In some embodiments, one or all of the memory devices 22A, 22B of FIGS. 2A and 2B may include memory device 200. While FIG. 2C shows a separate buffer die 202, as noted, in some embodiments, memory device 200 may be a buffer die such as buffer die 202, buffer die 23A, and/or buffer die 23B.

The memory device 200 includes a memory array 250. The memory array 250 includes a plurality of banks BANK0-15, each bank including a plurality of word lines WL, a plurality of bit lines BL, and a plurality of memory cells MC arranged at intersections of the plurality of word lines WL and the plurality of bit lines BL. Although sixteen banks are shown in FIG. 2, memory array 250 may include any number of banks. The selection of the word line WL is performed by a row decoder 240 and the selection of the bit line BL is performed by a column decoder 245. Sense amplifiers (SAMP) are located for their corresponding bit lines BL and connected to at least one respective local I/O line pair (LIOT/B), which is in turn coupled to at least respective one main I/O line pair (MIOT/B), via transfer gates (TG), which function as switches. The TG may be coupled to one or more read/write amplifiers (RWAMP) 255, which may be coupled to an error correction code (ECC) circuit 235. The ECC circuit 235 may be coupled to an IO circuit 260, which may be coupled to one or more external terminals of semiconductor device 200. Read data from the bit line BL is amplified by the sense amplifier SAMP, and transferred to read/write amplifiers 255 over complementary local data lines (LIOT/B), transfer gate (TG), and complementary main data lines (MIOT/B) to the ECC circuit 235. Conversely, write data outputted from the ECC circuit 235 is transferred to the sense amplifier SAMP over the complementary main data lines MIOT/B, the transfer gate TG, and the complementary local data lines LIOT/B, and written in the memory cell MC coupled to the bit line BL.

The memory device 200 may employ a plurality of external terminals that include command and address terminals coupled to a command/address (C/A) bus to receive command and address signals, clock terminals to receive clock signals CK_t and CK_c, data terminals DQ, RDQS, and power supply terminals VDD, VSS, and VDDQ.

The C/A terminals may be supplied with an address and a bank address signal from outside, for example, from a buffer die 202. Buffer die 202 may be buffer die 23A and/or buffer die 23B in some embodiments. The address signal and the bank address signal supplied to the address terminals are transferred, via a command/address input circuit 205, to an address decoder 212. The address decoder 212 receives the address signals and supplies a decoded row address signal XADD to the row decoder 240, and a decoded column address signal YADD to the column decoder 245. The address decoder 212 also receives the bank address signal BADD and supplies the bank address signal to the row decoder 240 and the column decoder 245.

The C/A terminals may further be supplied with command signals from, for example, buffer die 202. In some embodiments, buffer die 202 may receive commands and addresses from a controller, such as controller 106. The command signals may be provided as internal command signals ICMD to a command decoder 215 via the command/address input circuit 205. The command decoder 215 includes circuits to decode the internal command signals ICMD to generate various internal signals and commands for performing operations, for example, a row activation signal (ACT) to select a word line. Another example may be providing internal signals to enable circuits for performing operations, such as control signals to enable signal input buffers that receive clock signals.

Each bank BANK0-15 may be organized into multiple physical column planes (CP). Each column plane may be associated with multiple column selects (e.g., CS0-63, CS0-59, CS0-55). In some embodiments, different column planes may be used to store different types of information. For example, some column planes may store data and another plane stores ECC data. Optionally, a further plane may store global column redundancy (GCR) data. Optionally, the array 250 can store metadata in one or more column planes. In some embodiments, a column plane may store more than one type of information (e.g., data and metadata, metadata and ECC data)

The C/A terminals may receive an access command which is a read command. When a read command is received, and a bank address, a row address and a column address are timely supplied with the read command, a codeword including read data, metadata, and read ECC data (e.g., parity bits) is read from memory cells in the memory array 250 corresponding to the row address and column address. The read command is received by the command decoder 215, which provides internal commands so that read data from the memory array 250 is provided to the ECC circuit 235. The ECC circuit 235 may use the parity bits in the codeword to determine if the codeword includes any errors, and if any errors are detected, may correct them to generate a corrected codeword (e.g., by changing a state of the identified bit(s) which are in error). The corrected codeword is output from the data terminals DQ via the input/output circuit 260.

The C/A terminals may receive an access command which is a write command. When the write command is received, and a bank address, a row address, and a column address are timely supplied as part of the write operation, and write data is supplied through the DQ terminals to the ECC circuit 235. The write data (which may include write data and metadata) supplied to the data terminals DQ is written to a memory cells in the memory array 250 corresponding to the row address and column address. The write command is received by the command decoder 215, which provides internal commands so that the write data is received by data receivers in the input/output circuit 260. The write data is supplied via the input/output circuit 260 to the ECC circuit 235. The ECC circuit 235 may generate ECC data (e.g., a number of parity bits) based on the write data, and the write data and the parity bits may be provided as a codeword to the memory array 250 to be written into the memory cells MC.

While in the examples above, the ECC operations are described as being performed on the memory device 200, in some embodiments, some or all of the ECC operations may be performed by the buffer die 202. In these embodiments, the codewords and/or parity bits may be provided from the memory device 200 to the buffer die 202 during a read operation. The buffer die 202 may include an ECC circuit 206 that detects and corrects errors in the codeword and provides the corrected codeword (without the parity bits) to external DQ terminals. Similarly, during write operations, the ECC circuit 206 may generate ECC data and provide it to the memory device 200 for storage. In some embodiments where the buffer die 202 includes an ECC circuit 206, the memory device 200 may not include ECC circuit 235 and/or ECC circuit 235 may be disabled. However in other embodiments, the ECC operations may be divided between the buffer die 202 and memory device 200.

The command decoder 215 may access mode register 275 that is programmed with information for setting various modes and features of operation for the semiconductor device 200. For example, the mode register 275 may provide parameters that allow the semiconductor device 200 to operate at different frequencies, provide different burst lengths, allow banks BANK0-15 to be organized into different groups, operate in x8 or x16 mode, and/or other different operating conditions. In some embodiments, mode register 275 may include multiple registers.

The information in the mode register 275 may be programmed by providing the memory device 200 a mode register write command, which causes the memory device 200 to perform a mode register write operation. In some embodiments, data to be written to the mode register 275 is provided via the C/A terminals and/or the DQ terminals. The command decoder 215 accesses the mode register 275, and based on the programmed information along with the internal command signals provides the internal signals to control the circuits of the semiconductor device 200 accordingly. Information programmed in the mode register 275 may be externally provided by the memory device 200 using a mode register read command, which causes the memory device 200 to access the mode register 275 and provide the programmed information (e.g., to the buffer die 202). In some embodiments, the information may be provided via the C/A terminals and/or the DQ terminals.

Turning to the explanation of the external terminals included in the memory device 200, the clock terminals and data clock terminals are supplied with external clock signals and complementary external clock signals. The external clock signals CK_t, CK_c may be supplied to a clock input circuit 220. When enabled, input buffers included in the clock input circuit 220 pass the external clock signals. For example, an input buffer passes the CK_t and CK_c signals when enabled by a CKE signal from the command decoder 215. The clock input circuit 220 may use the external clock signals passed by the enabled input buffers to generate internal clock signal ICK. The internal clock signal ICK are supplied to internal clock circuit 230 for providing one or more clock signals to the various components of memory device 200.

The internal clock circuits 230 includes circuits that provide various phase and frequency controlled internal clock signals based on the received internal clock signals. For example, the internal clock circuits 230 may include a clock path (not shown in FIG. 2) that receives the ICK clock signal and provides internal clock signals ICK and ICKD to the command decoder 215. Optionally, the input/output circuit 260 may include clock circuits and driver circuits for generating and providing the RDQS signal to a controller.

The power supply terminals are supplied with power supply potentials VDD and VSS. These power supply potentials VDD and VSS are supplied to an internal voltage generator circuit 270. The internal voltage generator circuit 270 generates various internal potentials VPP, VOD, VARY, VPERI. The internal potential VPP is mainly used in the row decoder 240, the internal potentials VOD and VARY are mainly used in the sense amplifiers included in the memory array 250, and the internal potential VPERI is used in many other circuit blocks.

The power supply terminal is also supplied with power supply potential VDDQ. The power supply potentials VDDQ is supplied to the input/output circuit 260 together with the power supply potential VSS. The power supply potential VDDQ may be the same potential as the power supply potential VDD in an embodiment of the disclosure. The power supply potential VDDQ may be a different potential from the power supply potential VDD in another embodiment of the disclosure. However, the dedicated power supply potential VDDQ is used for the input/output circuit 260 so that power supply noise generated by the input/output circuit 260 does not propagate to the other circuit blocks.

Returning to the ECC circuit 235, typical ECC encoding/decoding techniques, such as Hamming coding, utilize 128 bits of data (e.g., data, metadata, or a combination) to generate 8 parity bits to form a codeword of 136 bits. However, these techniques usually can only correct one error in the codeword, and sometimes detect up to two errors. In contrast, Reed Solomon (RS) coding can correct a larger number of errors. RS coding techniques may generate 128 parity bits for 512 bits of data (or data and metadata), for a codeword of 640 bits. The RS coding may be capable of correcting up to 64 errors in the codeword. This is a higher level of correction capability compared to Hamming or other error coding schemes. However, RS requires more parity bits and is more computationally complex.

According to embodiments of the present disclosure, a memory package including memory device 200 may utilize a parallel RS implementation. For example, one or more memory devices may perform a portion of the RS coding, and the buffer die may perform another portion of the RS coding. The memory devices and/or buffer die may perform some or all of the RS coding in parallel (e.g., one or more computations are at substantially the same time). In some embodiments, portions of the codeword may be stored across one or more of the memory devices and/or buffer die. By utilizing one or more memory devices and the buffer die for RS coding, the burden may be distributed, making RS coding temporally and/or computationally feasible for memory packages. This may allow memory packages to have greater error correction capabilities.

While reference is made to parity bits and ECC data, and storing parity bits and/or ECC data in portions of a memory array configured to store ECC data, in some applications, the ECC data (which may include parity bits) may not be differentiated from data and/or metadata. When an ECC circuit receives data (which may include metadata), it may generate a codeword which has more bits than the number of bits of the original data. While these additional bits are referred to as parity bits/ECC data, all may be codeword bits, depending on the coding scheme employed by the memory device and/or memory package. In other words, there is no differentiation between bits of the codeword corresponding specifically to data and bits of the codeword corresponding specifically to the parity bits.

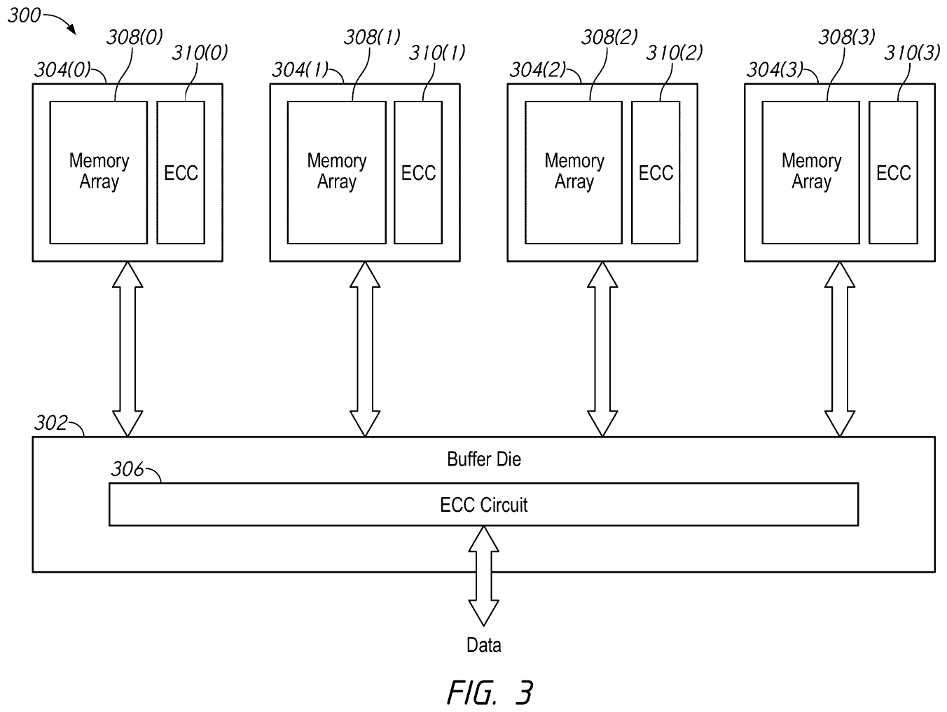

FIG. 3 is a functional block diagram of a memory package according to at least one embodiment of the disclosure. Memory package 300 may include a buffer die 302 and one or more memory devices 304. While four memory devices 304(0-3) are shown in FIG. 3, any number of memory devices 304 may be included. In some embodiments, the memory devices 304 may include memory device 200 shown in FIG. 2C. Each memory device 304 may include a memory array 308(0-3) that may include a portion configured to store data and a portion configured to store ECC data. In some embodiments, the data portion and/or ECC data portion may include one or more column planes. In some embodiments, the memory arrays 308(0-3) may include memory array 250. The memory devices 304 may further include an ECC circuit 310(0-3). In some embodiments, the ECC circuits 310(0-3) may include ECC circuit 235. The buffer die 302 may include an ECC circuit 306. The ECC circuit 306 may include ECC circuit 206 in some embodiments. In some embodiments, buffer die 302 may include buffer die 202, buffer die 23A, and/or buffer die 23B. In some embodiments, the memory package 300 may be used to implement one or more of memory packages 104 shown in FIG. 1B. FIG. 3 is a functional block diagram, and the arrangement of the components is to illustrate the passing of information between components and is not meant to reflect the physical arrangement of the components.

The memory package 300 may employ a Reed Solomon encoding scheme for error detection and correction. The computations of calculating the codeword from received data (e.g., during a write operation) and calculating the syndrome of a codeword (e.g., during a read operation) may be divided between the memory devices 304(0-3) and the buffer die 302.

For example, the codeword may be stored in the memory devices 304(0-3) such that each memory device 304 has a group of consecutive coefficients stored in memory array 308. During a read operation each memory device 304 may make computations for its set of coefficients with the ECC circuit 310, and provide an output of the computations to the buffer die 302. The buffer die 302 may combine the results from the memory devices 304(0-3) and calculate the syndrome with the ECC circuit 306. In other embodiments, the memory devices 304(0-3) may calculate different portions of the syndrome and provide the portions to the ECC circuit 306 to arrange and/or combine into the full syndrome for the codeword. The ECC circuit 306 may correct errors in the codeword based on the syndrome and output the corrected data (if any corrections are necessary).

Continuing the example, during a write operation, the ECC circuit 306 may organize write data and provide it to the memory devices 304(0-3). The ECC circuits 310(0-3) may each perform computations for the codeword based on the write data received. The results may be provided to the ECC circuit 306, and the ECC circuit 306 may calculate the final codeword. The codeword may then be distributed to the memory devices 304(0-3) for storage in the memory arrays 308(0-3). In other embodiments, the ECC circuit 306 may do the preliminary computations on the data, and distribute those preliminary results to the memory devices 304(0-3). The ECC circuits 310(0-3) may perform the final computations on the received portion of the results from the ECC circuit 306, and the ECC circuits 310(0-3) may then provide the result (e.g., a portion of the codeword) to the corresponding memory array 308(0-3) for storage. In still other embodiments, the ECC circuit 306 performs all of the computations on the write data to generate the codeword and provides portions of the codeword to one or more of the memory devices 304(0-3).

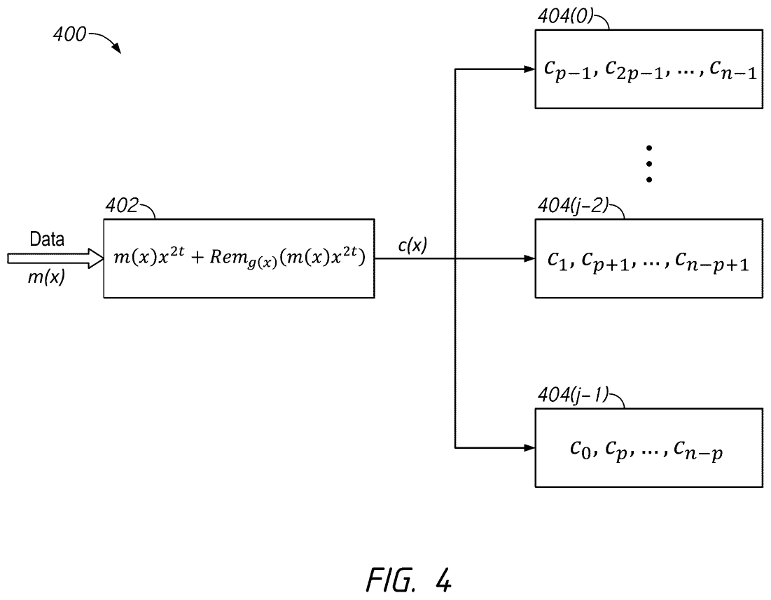

FIG. 4 illustrates division of computations for a write operation in a memory package according to at least one embodiment of the disclosure. Memory package 400 may include a buffer die and one or more memory devices. In the example shown, the memory package 400 includes j memory devices. The buffer die 402 may be included in buffer die 202 and/or 302 in some embodiments. The memory devices 404(0-j−1) may be include memory devices 304 and/or memory device 200 in some embodiments.

For Reed Solomon (RS) coding, a generator polynomial may be constructed. An example generator polynomial is provided in Equation 1:

$$g ( x ) = ( x + {α}^{1} ) ( x + {α}^{2} ) … ( 1 + {α}^{2 t} ) \qquad Equation ( 1 )$$

Where t is error correction capability of the RS coding and a is a primitive element. To encode data of k-bits, a n-bit codeword is generated:

$$c ( x ) = m ( x ) {x}^{2 t} + {Rem}_{g ( x )} ( m ( x ) {x}^{2 t} ) \qquad Equation ( 2 )$$

Where c(x) is the codeword, m(x) is the data encoded, and Rem is the remainder polynomial of dividing m(x)x^{2t} by g(x).

In the embodiment shown in FIG. 4, during a write operation, the buffer die 402 receives the data, and the codeword is calculated by the buffer die 402 (e.g., by the ECC circuit of the buffer die) using Equations (1) and (2). The buffer die 402 divides the bits of the codeword across one or more of the memory devices 404 for storage. Thus, in some embodiments, a memory device 404 may store a portion of the codeword, not the entire codeword. The bits of the portion of the codeword may be stored in column planes of the memory array configured to store data, ECC data, and/or metadata.

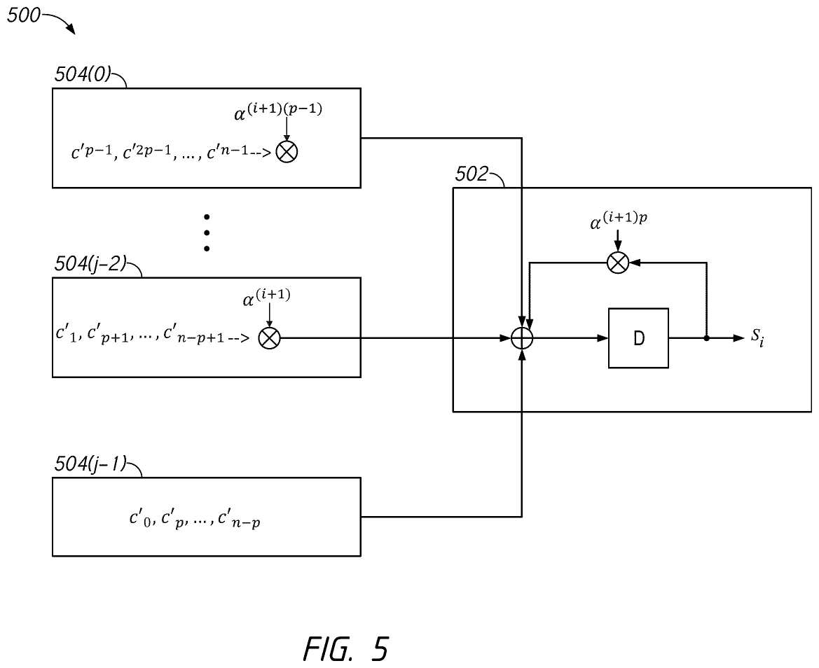

FIG. 5 illustrates division of computations for a read operation in a memory package according to at least one embodiment of the disclosure. Memory package 500 may include a buffer die and one or more memory devices. In the example shown, the memory package 500 includes j memory devices. The buffer die 502 may be included in buffer die 202, 302, and/or 402 in some embodiments. The memory devices 504(0-j−1) may be include memory device 200, memory devices 304, and/or memory devices 404 in some embodiments.

During a read operation (e.g., responsive to a read command received by the memory package), the codeword may be retrieved from one or more of the memory devices 504. The memory devices 504 may perform computations on the respective portions of the codeword in order to determine a syndrome of the codeword. The ECC circuits of the memory devices 504 may perform the computations in some embodiments. The syndrome allows the detection of errors and determination of the locations of the errors in the codeword (if any).

The codeword retrieved from the memory arrays of the memory devices 504 is provided as:

$${c}^{′} ( x ) = {c}_{n - 1}^{′} {x}^{n - 1} + … + {c}_{1}^{′} {x}^{1} + {c}_{0}^{′} \qquad Equation ( 3 )$$

The syndrome for the received codeword c′(x) is calculated by:

$${S}_{i} = ( … ( {c}_{n - 1}^{′} {α}^{i + 1} + {c}_{n - 2}^{′} ) {α}^{i + 1} + … ) {α}^{i + 1} + {c}_{0}^{′} \qquad Equation ( 4 )$$

Horner's rule allows at least a portion of Equation 4 to be computed in parallel as shown in the embodiment of FIG. 5. By grouping p consecutive coefficients of c′(x), the memory devices 504 can perform a parallel syndrome computation as shown in FIG. 5. The results of the parallel computations by the memory devices 504 are provided to the buffer die 502 to make the final computation of the syndrome. The syndrome may be provided to other components (e.g., other components of the ECC circuit) of the buffer die 502 to find the locations of errors in the read data and the errors may be corrected. The corrected data may then be output by the buffer die 502 (e.g., to a controller).

The embodiment shown in FIGS. 4 and 5 is provided merely as a non-limiting example, and other divisions of the computations for RS encoding and decoding between the memory devices and buffer die may be used in other embodiments. For example, in some embodiments, the memory devices may perform computations on write data to prepare the codeword and provide the results to the buffer die. The buffer die may make further computations based on the results to generate the codeword (e.g., multiplying the results provided by the memory devices by a remainder polynomial matrix). The codeword may then be stored in one or more of the memory devices. During a read operation, the memory devices may perform computations to determine the syndrome in parallel. The buffer die may receive the syndrome from the memory devices and correct errors in the codeword as necessary and output the corrected data.

In some embodiments, the buffer die may facilitate transferring data between memory devices if the memory devices require portions of the codeword stored in other memory devices for performing the computations. In some embodiments, the buffer die may include registers and/or a memory array (e.g., similar or the same as memory array 250 of memory device 200) configured to store information for computing the codeword and/or the syndrome. For example, the buffer die may store a remainder polynomial matrix. In another example, the buffer die may store information indicating portions and locations of a codeword are stored in the memory devices.

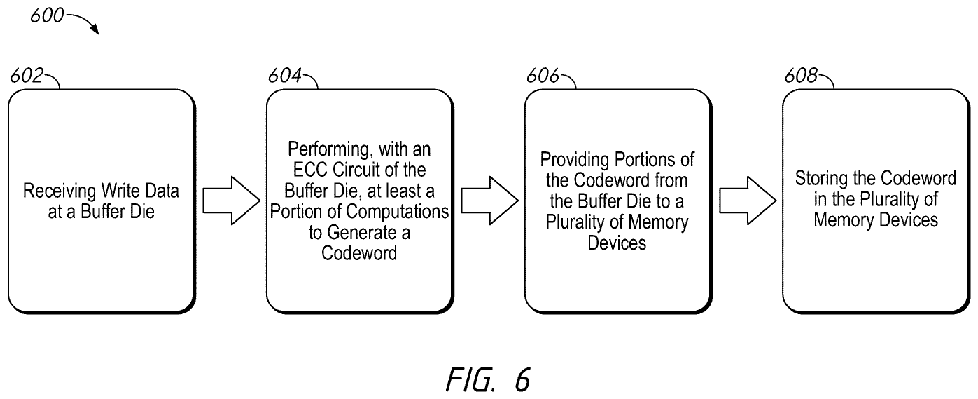

FIG. 6 is a flow chart of a method according to at least one embodiment of the present disclosure. The method shown in flowchart 600 may be performed in whole or in part by a buffer die and/or a memory device as described in one or more embodiments disclosed herein.

At block 602, “receiving write data at a buffer die” may be performed. In some embodiments, the write data may be received with an associated write command associated at the buffer die. At block 604 “performing, with an ECC circuit of the buffer die, at least a portion of computations to generate a codeword” may be performed. The codeword may be based, at least in part, on the write data. The codeword may be generated using Reed Solomon (RS) coding in some embodiments. In some embodiments, the write data comprises 512 bits and the code word comprises 640 bits.

At block 606, “providing portions of the codeword from the buffer die to a plurality of memory devices” may be performed. At block 608, “storing the codeword in the plurality of memory devices” may be performed. The codeword may be stored in column planes of the memory arrays of the memory devices in some embodiments. In some embodiments, some of the bits of the codeword may be stored in column planes associated with data. In some embodiments, the codeword may be stored in column planes associated with ECC data. In some embodiments, the codeword may be stored in column planes associated with metadata. In some embodiments, the codeword may be stored in a combination of column planes associated with different types of data.

Optionally, the method in flowchart 600 may further include “performing at least a second portion of the computations to generate the codeword with a plurality of ECC circuits included in corresponding ones of the plurality of memory devices. In some embodiments, the second portion of the computations are performed in parallel. In some embodiments, results of the second portion of the computations are provided to the ECC circuit of the buffer die, and the at least a portion of the computations performed by the ECC circuit are based, at least in part, on the results. In other words, in some embodiments, the buffer die computes the codeword. In other embodiments, the buffer die and the memory devices both perform computations to calculate the codeword.

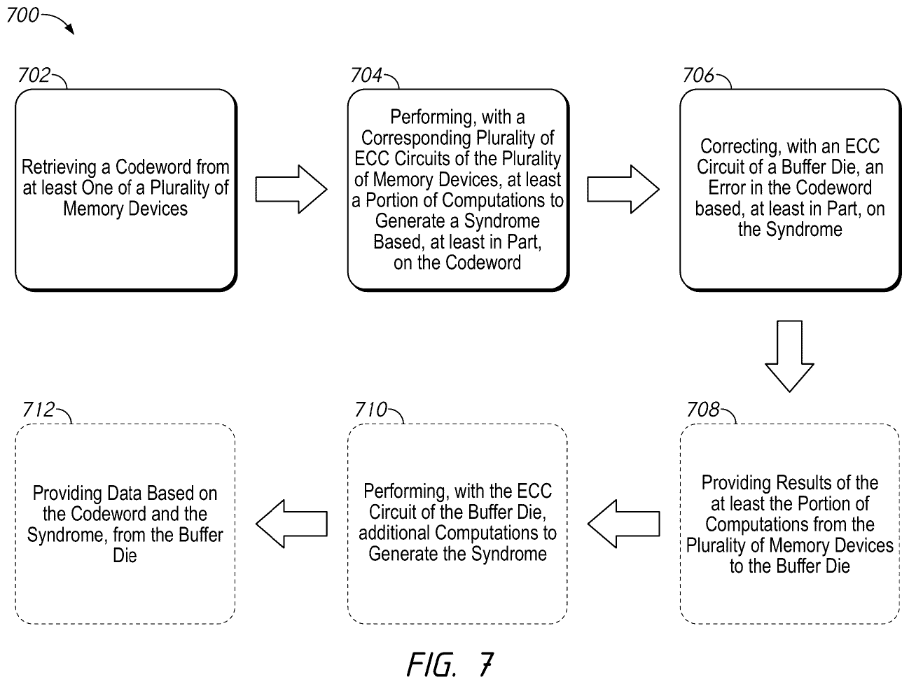

FIG. 7 is a flow chart of a method according to at least one embodiment of the present disclosure. The method shown in flowchart 700 may be performed in whole or in part by a buffer die and/or a memory device as described in one or more embodiments disclosed herein.

At block 702, “retrieving a codeword from at least one of a plurality of memory devices” may be performed. In some embodiments, different portions of the codeword may be retrieved from different ones of the plurality of memory devices. In some embodiments, the codeword was generated from data using Reed Solomon (RS) coding. In some embodiments, the codeword is retrieved responsive to receiving a read command at a buffer die from a controller.

At block 704, “performing, with a corresponding plurality of ECC circuits of the plurality of memory devices, at least a portion of computations to generate a syndrome based, at least in part, on the codeword” may be performed. In some embodiments, the corresponding plurality of ECC circuits of the plurality of memory devices perform the at least the portion of computations in parallel. By parallel, it is meant that two or more of the memory devices perform at least one computation at substantially the same time (e.g., one memory device performs at least part of a computation while another memory device is performing at least part of a computation).

At block 706, “correcting, with an ECC circuit of a buffer die, an error in the codeword based, at least in part, on the syndrome” may be performed.

In some embodiments, the method shown in flowchart 700 may further include block 708 where “providing results of the at least the portion of computations from the plurality of memory devices to the buffer die” is performed, and block 710 where “performing, with the ECC circuit of the buffer die, additional computations to generate the syndrome” are performed. In other words, in some embodiments, the memory devices calculate the syndrome, and in other embodiments, the memory devices and the buffer die both perform computations to calculate the syndrome.

In some embodiments, the method shown in flowchart 700 further includes “providing data based on the codeword and the syndrome, from the buffer die” as indicated by block 712. In some embodiments, the data may be provided to a controller.

The apparatuses, systems, and methods disclosed herein may allow for more time-efficient computation of codewords and syndromes for Reed Solomon (RS) coding. This may allow memory packages to utilize the higher error correction capabilities of RS coding, compared to Hamming coding.

Of course, it is to be appreciated that any one of the examples, embodiments or processes described herein may be combined with one or more other examples, embodiments and/or processes or be separated and/or performed amongst separate devices or device portions in accordance with the present systems, devices and methods. For example, a buffer die may have all or some of the features of the buffer dice disclosed in the present application.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of memory devices, wherein each of the plurality of memory devices comprises an error correction code (ECC) circuit, wherein one or more of the plurality of memory devices is configured to store at least a portion of a codeword generated by Reed Solomon (RS) coding; and
a buffer die in communication with the plurality of memory devices, the buffer die comprising a second ECC circuit configured to correct errors in the codeword.

2. The apparatus of claim 1, wherein the ECC circuits of the plurality of memory devices are configured to perform computations for generating a syndrome for the codeword.

3. The apparatus of claim 2, wherein the second ECC circuit of the buffer die is configured to receive results of the computations performed by the plurality of memory devices and perform additional computations based on the results to generate the syndrome.

4. The apparatus of claim 2, wherein the computations are performed in parallel.

5. The apparatus of claim 2, wherein the second ECC circuit of the buffer die is configured to correct errors in the codeword based, at least in part, on the syndrome.

6. The apparatus of claim 1, wherein the second ECC circuit of the buffer die is configured to generate the codeword based, at least in part, on write data, and provide the at least the portion of the codeword to the one or more of the plurality of memory devices.

7. The apparatus of claim 1, wherein the ECC circuits of the plurality of memory devices are configured to perform computations for generating the codeword based, at least in part, on write data.

8. The apparatus of claim 7, wherein the second ECC circuit of the buffer die is configured to receive results of the computations performed by the plurality of memory devices and perform additional computations based on the results to generate the codeword.

9. The apparatus of claim 1, wherein the buffer die further comprises a memory array, a register, or a combination thereof configured to store information for computation of the codeword or a syndrome based on the codeword.

10. A method comprising:
receiving write data at a buffer die;
performing, with an error correction code (ECC) circuit of the buffer die, at least a portion of computations to generate a codeword based, at least in part, on the write data, using Reed Solomon (RS) coding;
providing portions of the codeword from the buffer die to a plurality of memory devices; and
storing the codeword in the plurality of memory devices.

11. The method of claim 10, further comprising performing at least a second portion of the computations to generate the codeword with a plurality of ECC circuits included in corresponding ones of the plurality of memory devices.

12. The method of claim 11, wherein the second portion of the computations are performed in parallel.

13. The method of claim 11, wherein results of the second portion of the computations are provided to the ECC circuit of the buffer die, and the at least a portion of the computations performed by the ECC circuit are based, at least in part, on the results.

14. The method of claim 10, wherein the write data comprises 512 bits and the codeword comprises 640 bits.

15. The method of claim 10, further comprising receiving a write command associated with the write data at the buffer die.

16. A method comprising:
retrieving a codeword from at least one of a plurality of memory devices, wherein the codeword was generated from data using Reed Solomon (RS) coding;
performing, with a corresponding plurality of error correction code (ECC) circuits of the plurality of memory devices, at least a portion of computations to generate a syndrome based, at least in part, on the codeword; and
correcting, with an ECC circuit of a buffer die, an error in the codeword based, at least in part, on the syndrome.

17. The method of claim 16, further comprising:
providing results of the at least the portion of computations from the plurality of memory devices to the buffer die; and
performing, with the ECC circuit of the buffer die, additional computations to generate the syndrome.

18. The method of claim 16, further comprising, providing data based on the codeword and the syndrome, from the buffer die.

19. The method of claim 16, receiving a read command at the buffer die from a controller.

20. The method of claim 15, wherein the corresponding plurality of ECC circuits of the plurality of memory devices perform the at least the portion of computations in parallel.
